(19) United States
(12) Patent Application Publication
(10) Pub. No.: US 2009/0297302 A1
(43) Pub. Date: Dec. 3, 2009

(54) WAFER CONVEYANCE METHOD AND WAFER CONVEYANCE DEVICE

(75) Inventor: Shinji Sakamoto, Omura-shi (JP)

Correspondence Address: SHEEHAN PHINNEY BASS & GREEN, PA;c/o PETER NIEVES, 1000 ELM STREET, MANCHESTER, NH, 03105-3701, US

(73) Assignee: SUMCO TECHXIV CORPORATION, Omura-shi (JP)

(21) Appl. No.: 12/468,576

(22) Filed: May 19, 2009

(30) Foreign Application Priority Data
Jun. 2, 2008 (JP) 2008-145000

(51) Int. Cl. H01L 21/677

(52) U.S. Cl. 414/222.01; 414/806

(57) ABSTRACT

In order to make it possible to reduce the occurrence of physical damage to wafers during conveyance, a state is established in which wafers W are contained in a wafer cassette 1 standing approximately vertically, and the wafer cassette 1 is conveyed, in this state in which the wafers W are contained in the wafer cassette 1 standing approximately vertically, so that the planes of the wafers W are approximately parallel to the direction of conveyance. Since the wafers are kept in the state of standing approximately vertically, it is possible to reduce the occurrence of bending, as happens when they are held horizontally. Moreover, since the wafer cassette 1 is conveyed while keeping the planes of the wafers approximately parallel to the direction of conveyance, accordingly it is possible to reduce the increase of weight which acts upon the wafers W in the direction perpendicular to their planes caused by acceleration due to vertical shifting, horizontal shifting, or vertical vibration; and therefore it is possible to reduce the occurrence of bending of the wafers W.

### CROSS-REFERENCE TO PRIOR APPLICATION

This application relates to and claims the benefit of priority from Japanese Patent Application number 2008-145000, filed on Jun. 2, 2008 the entire disclosure of which is incorporated herein by reference.

### BACKGROUND

The present invention relates to a wafer conveyance method and a wafer conveyance device which contains wafers in a conveyance container and conveys them.

Generally, a silicon wafer is manufactured from an ingot by various processes such as slicing, beveling, wrapping or double-sided polishing, etching, mirror polishing, washing, and so on.

Between these various processes, it is necessary to convey the wafer which is the subject of processing from each earlier process which has been completed, to a subsequent later process.

As one method of conveying the wafers which are the processing subjects between such processes, it has been practiced to hold a large number of the wafers horizontally in a wafer cassette, and to convey them to the intake of the next processing in this wafer cassette (for example, refer to Patent Reference #1).

During this conveyance, if for example the diameter of the wafers is 300 mm, 13 or 25 wafers may be held in the wafer cassette.

Patent Reference #1: Japanese Laid-Open Patent Publication 2005-101445.

### SUMMARY

The wafer cassette described in Patent Reference #1 holds the wafers by supporting them near their edges. Due to this, there is a fear that the wafers themselves may bend due to their own weight, and that they may be physically damaged by being broken or chipped or the like. Moreover, when conveyance of the wafers in a horizontal state is performed, due to acceleration caused by vibration in the vertical direction during conveyance, weight increase takes place in the direction in which bending of the wafers can easily occur (i.e. in the direction perpendicular to the planes of the wafers), so that the possibility that physical damage may occur is increased. Moreover, when the wafers are conveyed in a horizontal state, there is a fear that particles may adhere upon the wafers during transportation.

Furthermore, in recent years, a major increase of wafer diameter from wafers of 300 mm diameter to wafers of 450 mm diameter has progressed rapidly, and, the more the diameter of the wafers increases in this manner, the greater the above described possibility of the occurrence of physical damage becomes. Moreover, with 13 or 25 wafers of 450 mm diameter being held in a wafer cassette, the total weight of the wafer cassette containing the wafers is greater than 10 kg if it contains (for example) 13 wafers, and becomes about 20 kg if it contains 25 wafers; and accordingly conveyance of the cassette containing the wafers becomes difficult. Yet further, when conveying wafers of diameter 450 mm, the area and the volume of the path over which the wafers are conveyed are increased.

The present invention has been conceived in the light of the problems described above, and its object is to provide a technique which can reduce the occurrence of physical damage to the wafers during conveyance.

In order to attain the object described above, a wafer conveyance method according to a first aspect of the present invention is a wafer conveyance method in which wafers are loaded into a conveyance container and are conveyed, comprising: a loading step of establishing a state in which a predetermined number of the wafers are loaded into the conveyance container standing approximately vertically; and a conveyance step of conveying said conveyance container, in the state in which the wafers are contained within the conveyance container while standing approximately vertically, so that the planes of the wafers are approximately parallel to the direction of conveyance. Since, according to this method, the wafers are put into the state of standing approximately vertically upright within the conveyance container, accordingly it is possible to reduce the occurrence of bending, such as occurs when the wafers are held horizontally. Moreover, since the conveyance container is conveyed so that the planes of the wafers are kept approximately parallel to the direction of conveyance, and since thus it is possible to reduce the influence of increase of weight due to acceleration caused by vertical shifting, horizontal shifting, or vertical vibration of the conveyance container in the direction in which the wafers can easily be bent (i.e. the direction perpendicular to the planes of the wafers), accordingly it is possible to reduce the occurrence of bending of the wafers, and it is possible to reduce the occurrence of physical damage to the wafers.

Furthermore, with the wafer conveyance method described above, it would be acceptable to arrange for a short side of the bottom surface of the conveyance container, in the state in which the wafers are contained therein standing approximately vertically, to be shorter than the diameters of the wafers. According to this method, it is possible to reduce the conveyance path area which is required for conveying the conveyance container, as compared with the case when the wafers are conveyed horizontally.

Moreover, with the wafer conveyance method described above, it would be acceptable to arrange for the conveyance container to be adapted to be able selectively to assume either a first state in which it can contain the wafers approximately horizontally, or a second state in which it can contain the wafers approximately vertically; and for the loading step to comprise: a step of putting the conveyance container into the first state, and loading the wafers into said conveyance container approximately horizontally; and a step of putting the conveyance container into the second state, so that the wafers contained in the conveyance container are put into the state of standing approximately vertically. According to this method, for example, for wafers which have been processed in an earlier process in a horizontal state, it is possible to load them into the conveyance container horizontally, and, by transferring the conveyance container into the second state, it is possible to put the wafers into the state of standing up approximately vertically.

Yet further, with the wafer conveyance method described above, it would be acceptable to arrange for the predetermined number of wafers to be a number of wafers which are batch processed in at least one of a process directly before and a process directly after the conveyance thereof. According to this method, it is possible to convey the number of wafers which are batch processed in the processing process directly before in an appropriate manner, or to convey the number of wafers which are to be batch processed in the processing process directly after in an appropriate manner.

Furthermore, a wafer conveyance device according to a second aspect of the present invention is a wafer conveyance device which conveys wafers, comprising: a conveyance container which can contain up to a predetermined number of the wafers standing approximately vertically; and a container conveyance unit which can convey the conveyance container, in the state in which the wafers are contained within the conveyance container while standing approximately vertically, so that the planes of the wafers are approximately parallel to the direction of conveyance. Since, according to this device, the wafers are put into the state of standing approximately vertically upright within the conveyance container, accordingly it is possible to reduce the occurrence of bending, such as occurs when the wafers are held horizontally. Moreover, since the conveyance container is conveyed so that the planes of the wafers are kept approximately parallel to the direction of conveyance, and since thus it is possible to reduce the influence of increase of weight due to acceleration caused by vertical shifting, horizontal shifting, or vertical vibration of the conveyance container in the direction in which the wafers can easily be bent (i.e. the direction perpendicular to the planes of the wafers), accordingly it is possible to reduce the occurrence of bending of the wafers, and it is possible to reduce the occurrence of physical damage to the wafers.

With the wafer conveyance device described above, it would be acceptable to arrange for a short side of the bottom surface of the conveyance container in the state in which the wafers are contained therein standing approximately vertically is shorter than the diameters of the wafers. According to this device, it is possible to reduce the conveyance path area which is required for conveying the conveyance container, as compared with the case when the wafers are conveyed horizontally.

Moreover, with the wafer conveyance device described above, it would be acceptable to arrange for the conveyance container to be adapted to be able selectively to assume either a first state in which it can contain the wafers approximately horizontally, or a second state in which it can contain the wafers approximately vertically; and for there to be further included a transfer unit which transfers the conveyance container from the first state to the second state, and puts the wafers contained in the conveyance container in the state of standing approximately vertically. According to this device, for example, for wafers which have been processed in an earlier process in a horizontal state, it is possible to load them into the conveyance container horizontally, and, by transferring the conveyance container into the second state, it is possible to put the wafers into the second of standing up approximately vertically.

Furthermore, with the wafer conveyance device described above, it would be acceptable to arrange for the predetermined number of wafers to be a number of wafers which are batch processed in at least one of a process directly before and a process directly after the conveyance thereof. According to this device, it is possible to convey the number of wafers which are batch processed in the processing process directly before in an appropriate manner, or to convey the number of wafers which are to be batch processed in the processing process directly after in an appropriate manner.

### BRIEF DESCRIPTION OF THE DRAWINGS

FIG. 1 is a structural diagram showing a wafer cassette according to an embodiment of the present invention; and

FIG. 2 is a figure for explanation of a wafer conveyance device and wafer conveyance processing according to an embodiment of the present invention.

### DESCRIPTION OF THE PREFERRED EMBODIMENTS

An embodiment of the present invention will now be explained with reference to the drawings. It should be understood that the embodiment described below is not to be considered as being limitative of the scope of the claims of the present invention in any way; and, moreover, all of the elements and combinations thereof explained in connection to this embodiment are not necessarily essential to the means of solution provided by the present invention.

First, a wafer cassette will be explained, which is one example of a conveyance container that is used in the wafer conveyance device according to this embodiment of the present invention.

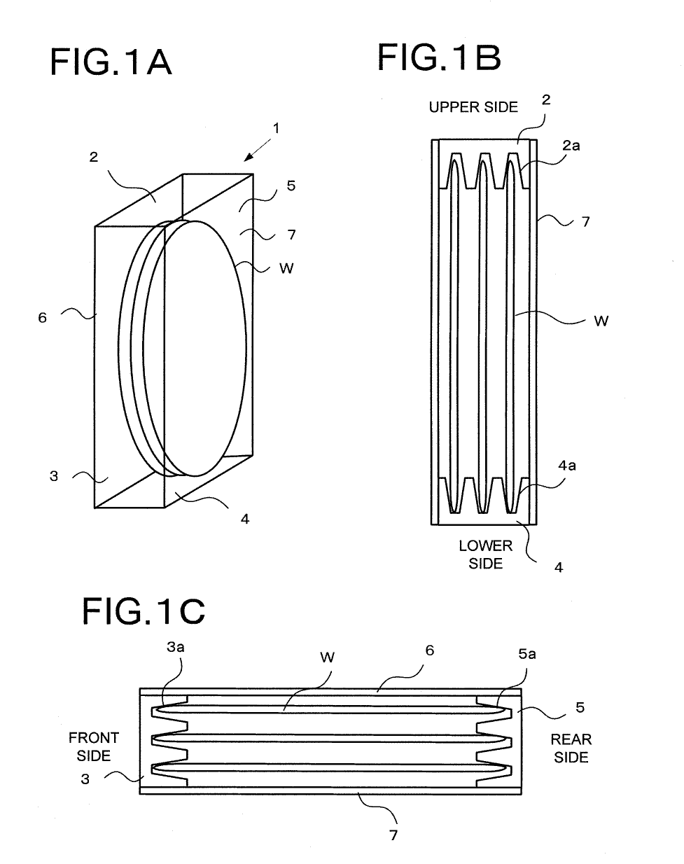

FIG. 1 is a structural diagram showing this wafer cassette which is included in the embodiment of the present invention. FIG. 1A is a cutaway perspective view showing an outline of the wafer cassette, FIG. 1B is a sectional view of the wafer cassette 1 cut vertically along a plane which is parallel to a side wafer support wall 3 thereof through its approximate center in its depth direction, and FIG. 1C is a sectional view of the wafer cassette 1 cut horizontally through its approximate center in its height direction.

As shown in FIG. 1A, this wafer cassette 1 has wafer support walls 2, 3, 4, and 5 and side walls 6 and 7, and an internal space is defined by these walls 2 through 7. It could also be arranged for this internal space to be sealed. A predetermined number of wafers W (for example one, three, five, etc.) can be stood up approximately vertically and held in this internal space. In this embodiment, this predetermined number of wafers is made to be, for example, the number of wafers which are processed by batch processing in a conveyance origin process before conveyance of the wafers by the wafer cassette 1 (an earlier first process), or the number of wafers which are processed by batch processing in a conveyance destination process after conveyance (a later second process). Since the number of wafers held in the wafer cassette 1 is limited to the number of wafers for batch processing in this manner, accordingly the weight of the wafer cassette 1 containing the wafers can be reduced, as compared to the prior art in which 13 or 25 wafers or similar were held. Moreover, in this embodiment, the short side of the bottom surface of the wafer cassette 1 is shorter than the diameter of the wafers W, in the state of the cassette 1 in which the wafers W can be held standing up approximately vertically. And, in this embodiment, the wafer support wall 2 is made to be capable of being opened and closed, so that, by opening the wafer support wall 2, it is possible to perform loading of wafers W into the wafer cassette 1, and taking of wafers W out therefrom.

As shown in FIG. 1B, for supporting the upper edge surfaces of the wafers W, the same number of concave portions 2a are provided in the wafer support wall 2 of the wafer cassette 1 as the number of wafers which can be held. Moreover, as also shown in FIG. 1B, for supporting the lower edge surfaces of the wafers W, the same number of concave portions 4a are provided in the wafer support wall 4 of the wafer cassette 1 as the number of wafers which can be held. With the wafer cassette 1 in this state, the lower edge surfaces of the wafers W are supported in the concave portions 4a of the wafer support wall 4, and their upper edge surfaces are supported in the concave portions 2a of the wafer support wall 2, so that they are in a state of being held approximately vertically.

Furthermore, as shown in FIG. 1C, for supporting the edge surfaces of the wafers W at the one sides thereof, the same number of concave portions 3a are provided in the wafer support wall 3 of the wafer cassette 1 as the number of wafers which can be held. Moreover, as also shown in FIG. 1C, for supporting the edge surfaces of the wafers W at their other sides, the same number of concave portions 5a are provided in the wafer support wall 5 of the wafer cassette 1 as the number of wafers which can be held. Thus, by the one side edge surfaces of the wafers W being supported in the concave portions 3a of the wafer support wall 3, and with their other side edge surfaces being supported in the concave portions 5a of the wafer support wall 5, the positions of the wafers W are regulated in the horizontal direction.

Next, the wafer conveyance device and the wafer conveyance method according to this embodiment of the present invention will be explained.

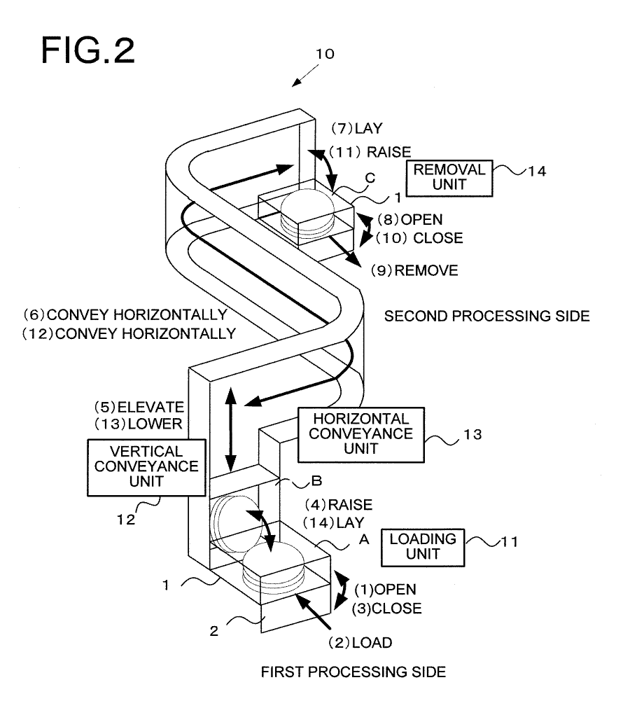

FIG. 2 is a figure for explanation of the wafer conveyance device and wafer conveyance method according to this embodiment of the present invention. It should be understood that, in FIG. 2, a plurality of wafer cassettes 1 are shown, in order to illustrate a plurality of successive states of a single wafer cassette 1.

As shown in FIG. 2, the wafer conveyance device 10 comprises a loading unit 11 that brings into a wafer cassette 1 wafers W which have been processed by a first process and which is one example of a transfer unit, a vertical conveyance unit 12 which conveys the wafer cassette 1 in the vertical direction and which is one example of a container conveyance unit, a horizontal conveyance unit 13 which conveys the wafer cassette 1 in the horizontal direction and which is one example of a container conveyance unit, and a removal unit 14 which removes the wafers W from the wafer cassette 1. The vertical conveyance unit 12 may have, for example, a vertically shiftable basket portion not shown in the figures upon which the wafer cassette 1 is mounted. And the horizontal conveyance unit 13 may have, for example, a rail portion not shown in the figures which extends along the conveyance path, and a trolley portion not shown in the figures upon which the wafer cassette 1 is mounted, and which is horizontally shiftable along that rail portion.

Next the wafer conveyance processing, in which the wafers W are conveyed from an earlier process (the first process) to a later process (the second process), will be explained. It should be understood that it will be supposed that, before this wafer conveyance processing, the wafer cassette 1 is in its state A in which it can hold the wafers W approximately horizontally. Moreover, it will be supposed that the number of wafers W which are batch processed in the first process and in the second process is the same (for example, three), and that the wafer cassette 1 can contain that number of wafers W (for example, three) which are batch processed (hereinafter termed the batch processing number).

In the wafer conveyance processing, first, the loading unit 11 opens the wafer support wall 2 of the wafer cassette 1 which is in the state A (see FIG. 2(1)), and, with an arm not shown in the figures, loads the batch processing number of wafers W which have been processed by the first process (FIG. 2(2)). Next, after having loaded the batch processing number of wafers W into the wafer cassette 1, the loading unit 11 closes the wafer support wall 2 of the wafer cassette 1 (FIG. 2(3)), and raises the wafer cassette 1, thus putting it into the state B in which it can be conveyed by the vertical conveyance unit 12 (FIG. 2(4)). Due to this, the wafers W in the wafer cassette 1 are put into the state of standing almost vertically.

Next, the vertical conveyance unit 12 elevates the wafer cassette 1 which is in its state B to a height at which it can be conveyed by the horizontal conveyance unit 13 (FIG. 2(5)). Here, in this elevation by the vertical conveyance unit 12, the wafer cassette 1 is conveyed so that the planes of the wafers W which are held in the wafer cassette 1 are kept approximately parallel to the direction of conveyance. Accordingly, it is possible to reduce the occurrence of bending of the wafers W, since the weight increase due to acceleration in the vertical direction which occurs during the shifting for elevation hardly acts at all in the direction in which the wafers W can easily be bent, in other words in the direction perpendicular to the planes of the wafers W. Moreover, since the short side of the bottom surface of the wafer cassette 1 during its vertical conveyance is shorter than the diameter of the wafers W, accordingly it is possible to reduce the conveyance area (i.e. the floor area) which is required for the conveyance path, as compared to a case when the wafers W are conveyed in a horizontal state.

Next, the horizontal conveyance unit 13 receives the wafer cassette 1 from the vertical conveyance unit 12, and conveys the wafer cassette 1 horizontally to a position in which it can be handled by the removal unit 14 which is equipped near the second processing area (FIG. 2(6)). In this embodiment, the horizontal conveyance unit 13 conveys the wafer cassette 1, in which the wafers W are being held in the state of standing approximately vertically, so that the planes of the wafers W are kept approximately parallel to the direction of conveyance. Accordingly, weight increase due to acceleration acting upon the wafers W along their fore and aft direction of conveyance during horizontal shifting, or due to acceleration acting thereupon in the vertical direction which occurs during the shifting, hardly acts at all in the direction in which the wafers W can easily be bent by acceleration, in other words in the direction which is perpendicular to the planes of the wafers W. Due to this, it is possible to reduce the occurrence of bending of the wafers W, so that it is possible to reduce the occurrence of physical damage to the wafers W. Moreover, since the short side of the bottom surface of the wafer cassette 1 during its vertical conveyance is shorter than the diameter of the wafers W, and since the wafer cassette 1 is conveyed with this short side approximately perpendicular to the direction of conveyance, accordingly the required width for the conveyance path is shorter as compared to the width which would be required if the wafers were to be conveyed in the horizontal state; and so it is possible to reduce the conveyance area (i.e. the floor area) which is required for the conveyance path, as compared to a case when the wafers W are conveyed in a horizontal state.

The removal unit 14 lays the wafer cassette 1, which has been conveyed by the horizontal conveyance unit 13, to its state C in which the wafers W within the wafer cassette 1 are in approximately the horizontal state (FIG. 2(7)). Next, the removal unit 14 opens the wafer support wall 2 (FIG. 2(8)), removes the batch processing number of wafers W from the wafer cassette 1 with an arm not shown in the figures, and conveys them to a predetermined position for the second process (FIG. 2(9)). And subsequently the removal unit 14 closes the wafer support wall 2 (FIG. 2(10)), and raises the wafer cassette 1, thus putting it into its state in which it can be conveyed by the horizontal conveyance unit 13 (FIG. 2(11)).

Next, the horizontal conveyance unit 13 conveys the wafer cassette 1 horizontally back to the position in which it can be processed by the vertical conveyance unit 12 (FIG. 2(12)). And then the vertical conveyance unit 12 lowers the wafer cassette 1 back to its position in which it can be processed by the loading unit 11 (FIG. 2(13)).

Next, the loading unit 11 lays the wafer cassette 1, which has been conveyed by the vertical conveyance unit 12, so that it reaches its state A in which wafers W can again be loaded into the wafer cassette 1 in the approximately horizontal state (FIG. 2(14)). Due to this, subsequently, it becomes possible to execute conveyance processing upon the next batch processing number of wafers W which have been processed by the first process.

Although the present invention has been explained above on the basis of an embodiment thereof, the present invention is not to be considered as being limited to that embodiment; various other variations are possible. For example, in the embodiment described above, it would also be acceptable to arrange to charge the internal space of the wafer cassette 1 positively while the wafers W are being conveyed. If this is done, then it is possible to prevent the adherence of foreign bodies to the wafers W from the exterior in an appropriate manner.

Moreover while, in the embodiment described above, a case was explained in which the number of wafers W which were batch processed in the first process and in the second process were the same, the present invention is not to be considered as being limited by this feature. For example, if the number of wafers W which are batch processed in the second process is less than the number which are batch processed in the first process, then it will be acceptable to provide a buffer which temporarily contains some of the wafers W in the area near the first processing area, in the area near the second processing area, or upon the conveyance path between them.

Furthermore while, in the embodiment described above, the path for vertical conveyance and the path for horizontal conveyance were combined together, the present invention is not to be considered as being limited by this feature; it would also be acceptable to provide only the vertical conveyance path or only the horizontal conveyance path, or to provide both the vertical conveyance path and the horizontal conveyance path, with at least one of these paths including a plurality of path elements.

Furthermore, in the embodiment described above, it would also be acceptable to arrange to convey the wafer cassette so that the planes of the wafers are approximately parallel to the direction of conveyance of the wafers, over only a portion of the conveyance path. By doing this as well, it is possible to reduce the occurrence of bending of the wafers W over that portion of the conveyance path, and to reduce the occurrence of physical damage to the wafers.

Furthermore while, in the embodiment described above, it was arranged to lay the wafer cassette 1, to insert the wafers W thereinto in the horizontal direction, and thereafter to raise the wafer cassette 1 so that the wafers W are standing approximately vertically, the present invention is not to be considered as being limited to this feature; it would also be acceptable to arrange to load the wafers W into the wafer cassette 1 in the state of standing approximately vertically.

Furthermore while, in the embodiment described above, a case was disclosed in which the conveyance used a single wafer cassette 1, the present invention is not limited to this feature; it would also be acceptable to arrange to convey the wafers W using a plurality of wafer cassettes 1. Moreover, over at least a portion of the wafer cassette conveyance path, it would also be acceptable to arrange to provide a plurality of paths for conveying the wafer cassettes 1. In this case, it would be acceptable to arrange to use at least one of these paths for conveying the wafer cassettes 1 from the first process to the second process, and to use the remaining paths for conveying the wafer cassettes 1 from the second process to the first process; or, alternatively, it would be possible to arrange to use all of the paths in a bidirectional manner for conveying the wafer cassettes 1 between the first process and the second process.

What is claimed is:

1. A wafer conveyance method in which wafers are loaded into a conveyance container and are conveyed, comprising:
a loading step of establishing a state in which a predetermined number of said wafers are loaded into said conveyance container standing approximately vertically; and
a conveyance step of conveying said conveyance container, in said state in which said wafers are contained within said conveyance container while standing approximately vertically, so that the planes of said wafers are approximately parallel to the direction of conveyance.

2. A wafer conveyance method according to claim 1, wherein a short side of the bottom surface of said conveyance container in said state in which said wafers are contained therein standing approximately vertically is shorter than the diameters of said wafers.

3. A wafer conveyance method according to claim 1, wherein said conveyance container is adapted to be able selectively to assume either a first state in which it can contain said wafers approximately horizontally, or a second state in which it can contain said wafers approximately vertically; and said loading step comprises:
a step of putting said conveyance container into said first state, and loading said wafers into said conveyance container approximately horizontally; and
a step of putting said conveyance container into said second state, so that said wafers contained in said conveyance container are put into the state of standing approximately vertically.

4. A wafer conveyance method according to claim 2, wherein said conveyance container is adapted to be able selectively to assume either a first state in which it can contain said wafers approximately horizontally, or a second state in which it can contain said wafers approximately vertically; and said loading step comprises:
a step of putting said conveyance container into said first state, and loading said wafers into said conveyance container approximately horizontally; and
a step of putting said conveyance container into said second state, so that said wafers contained in said conveyance container are put into the state of standing approximately vertically.

5. A wafer conveyance method according to claim 1, wherein said predetermined number of wafers is a number of wafers which are batch processed in at least one of a process directly before and a process directly after said conveyance thereof.

6. A wafer conveyance method according to claim 2, wherein said predetermined number of wafers is a number of wafers which are batch processed in at least one of a process directly before and a process directly after said conveyance thereof.

7. A wafer conveyance method according to claim 3, wherein said predetermined number of wafers is a number of wafers which are batch processed in at least one of a process directly before and a process directly after said conveyance thereof.

8. A wafer conveyance method according to claim 4, wherein said predetermined number of wafers is a number of wafers which are batch processed in at least one of a process directly before and a process directly after said conveyance thereof.

9. A wafer conveyance device which conveys wafers, comprising:
a conveyance container which can contain up to a predetermined number of said wafers standing approximately vertically; and
a container conveyance unit which can convey said conveyance container, in said state in which said wafers are contained within said conveyance container while standing approximately vertically, so that the planes of said wafers are approximately parallel to the direction of conveyance.

10. A wafer conveyance device according to claim 9, wherein a short side of the bottom surface of said conveyance container in said state in which said wafers are contained therein standing approximately vertically is shorter than the diameters of said wafers.

11. A wafer conveyance device according to claim 9, wherein said conveyance container is adapted to be able selectively to assume either a first state in which it can contain said wafers approximately horizontally, or a second state in which it can contain said wafers approximately vertically; and further comprising a transfer unit which transfers said conveyance container from said first state to said second state, and puts said wafers contained in said conveyance container in the state of standing approximately vertically.

12. A wafer conveyance device according to claim 10, wherein said conveyance container is adapted to be able selectively to assume either a first state in which it can contain said wafers approximately horizontally, or a second state in which it can contain said wafers approximately vertically; and further comprising a transfer unit which transfers said conveyance container from said first state to said second state, and puts said wafers contained in said conveyance container in the state of standing approximately vertically.

13. A wafer conveyance device according to claim 9, wherein said predetermined number of wafers is a number of wafers which are batch processed in at least one of a process directly before and a process directly after said conveyance thereof.

14. A wafer conveyance device according to claim 10, wherein said predetermined number of wafers is a number of wafers which are batch processed in at least one of a process directly before and a process directly after said conveyance thereof.

15. A wafer conveyance device according to claim 11, wherein said predetermined number of wafers is a number of wafers which are batch processed in at least one of a process directly before and a process directly after said conveyance thereof.

16. A wafer conveyance device according to claim 12, wherein said predetermined number of wafers is a number of wafers which are batch processed in at least one of a process directly before and a process directly after said conveyance thereof.
